(19) United States
(12) Patent Application Publication
(10) Pub. No.: US 2025/0112176 A1
(43) Pub. Date: Apr. 3, 2025

(54) FRAME STRUCTURES IN SEMICONDUCTOR PACKAGES

(71) Applicant: Apple Inc., Cupertino, CA (US)

(72) Inventors: Jiongxin LU, San Jose, CA (US); Kunzhong Hu, Cupertino, CA (US)

(73) Assignee: Apple Inc., Cupertino, CA (US)

(21) Appl. No.: 18/530,291

(22) Filed: Dec. 6, 2023

Related U.S. Application Data
(60) Provisional application No. 63/586,498, filed on Sep. 29, 2023.

(51) Int. Cl. H01L 23/00; H01L 21/56; H01L 23/28

(52) U.S. Cl. CPC H01L 23/562; H01L 21/56; H01L 23/28; H01L 24/08; H01L 24/80; H01L 2224/08145; H01L 2224/80895; H01L 2224/80896

(57) ABSTRACT

Various embodiments of an integrated circuit (IC) die package are disclosed. An IC die package includes an IC die, an interposer die electrically connected to the IC die, a first bonding structure disposed on the IC die, a second bonding structure bonded to the first bonding structure, a molding compound layer disposed on the second bonding structure and a frame structure disposed on the second bonding structure and surrounding the IC die.

### CROSS-REFERENCE TO RELATED APPLICATION

This application claims the benefit of U.S. Provisional Patent Application No. 63/586,498, filed Sep. 29, 2023, titled “Frame Structures in Semiconductor Packages,” which is incorporated by reference herein in its entirety.

### FIELD

This disclosure relates to semiconductor packages and, more particularly, to frame structures in integrated circuit (IC) die packages.

### BACKGROUND

An IC die package can include two or more IC dies (e.g., system-on-chips (SOCs), logic dies, and/or memory dies) mounted on a package substrate. Power and signal connections between the IC dies can be made through a routing layer. The two or more IC dies can be bonded to the routing layer through hybrid bonding structures and can be encapsulated in a molding compound layer. The molding compound layer can provide mechanical rigidity and environmental protection to the two or more IC dies to prevent moisture and handling damage.

### SUMMARY

Various embodiments of frame structures in an IC die package are disclosed. In some embodiments, a structure includes an IC die, an interposer die electrically connected to the IC die, a first bonding structure disposed on the IC die, a second bonding structure bonded to the first bonding structure, a molding compound layer disposed on the second bonding structure and a frame structure disposed on the second bonding structure and surrounding the IC die.

In some embodiments, an IC die package includes first and second IC dies, first and second bonding structures disposed on the first and second IC dies, respectively, a third bonding structure bonded to the first and second bonding structures and disposed on a substrate, a molding compound layer surrounding each of the first and second IC dies, and a frame structure surrounding each of the first and second IC dies and disposed in the molding compound layer.

In some embodiments, a method for fabricating an IC die package with a frame structure includes forming a first bonding structure on an IC die, forming a second bonding structure on an interposer die, performing a bonding process between the first and second bonding structures, attaching a frame structure on a top surface of the second bonding structure, and performing a molding process to form a molding compound layer surrounding the IC die and the frame structure.

### BRIEF DESCRIPTION OF THE DRAWINGS

Aspects of this disclosure are best understood from the following detailed description when read with the accompanying figures.

FIG. 1A illustrates a cross-sectional view of a frame structure in an IC die package, in accordance with some embodiments.

FIG. 1B illustrates a top-down view of a frame structure in an IC die package, in accordance with some embodiments.

FIG. 2A illustrates a cross-sectional view of a frame structure in another IC die package, in accordance with some embodiments.

FIG. 2B illustrates a top-down view of a frame structure in another IC die package, in accordance with some embodiments.

FIG. 3A illustrates a cross-sectional view of a frame structure in another IC die package, in accordance with some embodiments.

FIG. 3B illustrates a top-down view of a frame structure in another IC die package, in accordance with some embodiments.

FIG. 3C illustrates a cross-sectional view of a frame structure in another IC die package, in accordance with some embodiments.

FIG. 4 is a flow diagram of a method for fabricating an IC die package with a frame structure, in accordance with some embodiments.

FIG. 5 illustrates a cross-sectional view of an IC die package at a stage of its fabrication process, in accordance with some embodiments.

FIG. 6 illustrates a cross-sectional view of an IC die package at a stage of its fabrication process, in accordance with some embodiments.

FIG. 7 illustrates a cross-sectional view of an IC die package at a stage of its fabrication process, in accordance with some embodiments.

FIG. 8 illustrates a cross-sectional view of an IC die package at a stage of its fabrication process, in accordance with some embodiments.

FIG. 9 illustrates a cross-sectional view of an IC die package at a stage of its fabrication process, in accordance with some embodiments.

FIG. 10 illustrates a cross-sectional view of an IC die package at a stage of its fabrication process, in accordance with some embodiments.

FIG. 11 illustrates a cross-sectional view of an IC die package at a stage of its fabrication process, in accordance with some embodiments.

FIG. 12 illustrates a cross-sectional view of an IC die package at a stage of its fabrication process, in accordance with some embodiments.

FIG. 13 illustrates a cross-sectional view of an IC die package at a stage of its fabrication process, in accordance with some embodiments.

FIG. 14 illustrates a cross-sectional view of an IC die package with a frame structure at a stage of its fabrication process, in accordance with some embodiments.

FIG. 15 illustrates a cross-sectional view of an IC die package with a frame structure in molding compound layer at a stage of its fabrication process, in accordance with some embodiments.

FIG. 16 illustrates a cross-sectional view of an IC die package with a frame structure in molding compound layer at a stage of its fabrication process, in accordance with some embodiments.

FIG. 17 illustrates a cross-sectional view of an IC die package with a frame structure in molding compound layer at a stage of its fabrication process, in accordance with some embodiments.

FIG. 18 illustrates a cross-sectional view of an IC die package with a frame structure in molding compound layer at a stage of its fabrication process, in accordance with some embodiments.

FIG. 19 illustrates exemplary systems or devices that can include different IC die packages with frame structures, in accordance with some embodiments.

Illustrative embodiments will now be described with reference to the accompanying drawings. In the drawings, like reference numerals generally indicate identical, functionally similar, and/or structurally similar elements. The discussion of elements with the same annotations applies to each other, unless mentioned otherwise.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., +1%, ±2%, +3%, ±4%, +5% of the value). These values are merely examples and are not intended to be limiting. The terms “about” and “substantially” can refer to a percentage of the values as interpreted by those skilled in relevant art(s) in light of the teachings herein.

An IC die (also referred to as an “IC chip”) can include a compilation of layers with different functionality, such interconnect structures, power distribution networks, logic chips, memory chips, and the like. An IC die package (also referred to as a “semiconductor package”) can include multiple IC dies disposed on and electrically connected to one or more interposers dies having interconnect structures (e.g., through-silicon vias, metal lines, and metal vias), which can be disposed on and/or electrically connected to a package substrate. The interposer die and/or package substrate can provide electrical connections (also referred to as “signal transmission paths” or “metal routings”) between IC dies on the same interposer die and/or between IC dies on different interposer dies.

The IC dies can be bonded to the interposer die through top and bottom hybrid bonding structures in a hybrid bonding process. Each of the top hybrid bonding structures can be disposed on and electrically connected to interconnect structures of the IC dies. The bottom hybrid bonding structure can be disposed on and electrically connected to metal lines in the interposer die. Each of the top and bottom hybrid bonding structures can include a dielectric layer and conductive structures disposed in the dielectric layer. The top surfaces (also referred to as “bonding surfaces”) of the top hybrid bonding structures can be brought into contact with the top surface of the bottom hybrid bonding structure during the hybrid bonding process to form fusion bonds between the dielectric layers (e.g., oxide-to-oxide bonds) and metal bonding between the conductive structures (e.g., copper-to-copper bonds).

Each of the IC dies along with the top hybrid bonding structures can be surrounded by a molding compound layer (e.g., a polymeric material layer). The spaces between adjacent IC dies and adjacent hybrid bonding structures can be filled with the molding compound layer. The molding compound layer can be disposed directly on the sidewalls of the IC dies and the top hybrid bonding structures and on the top surface of the bottom hybrid bonding structure. The interface between the molding compound layer and the bottom hybrid bonding structure can be substantially coplanar with the hybrid bonding interfaces between the top and bottom hybrid bonding structures. The molding compound layer can provide mechanical stability and environmental protection to the IC dies and the hybrid bonding structures.

One of the challenges of manufacturing reliable IC die packages is preventing delamination at the hybrid bonding interfaces due to stress induced by the molding compound layer during fabrication and/or reliability testing of the IC die packages. The molding compound layer can have a higher thermal expansion coefficient than that of the materials of the IC dies and/or the hybrid bonding structures. As a result, the molding compound layer can have a greater thermal expansion than that of the IC dies and/or the hybrid bonding structures during high temperature processes performed in the fabrication and/or reliability testing of the IC die packages. Such differences in the thermal expansions can induce peeling stress in the hybrid bonding interfaces at the corner and/or edges of the IC dies as the molding compound layer is disposed adjacent to the hybrid bonding interfaces without having any space available for thermal expansion. The molding compound layer is constrained on the sides by the IC dies, on the bottom side by the bottom hybrid bonding structure, and on the top side by a carrier substrate.

To address the abovementioned challenges, the present disclosure provides example frame structures in IC die packages and example methods of forming the frame structures. In some embodiments, the IC dies along with the top hybrid bonding structures in the IC die package can be surrounded by a frame structure. The frame structure can be in a molding compound layer surrounding the IC dies. In some embodiments, the frame structure can include a material with a thermal expansion coefficient lower than the thermal expansion coefficient of the molding compound layer. In some embodiments, the thermal expansion coefficient of the material can be between the thermal expansion coefficients of the molding compound layer and the IC dies. In some embodiments, the thermal expansion coefficient of the material can be closer to the thermal expansion coefficient (e.g., about 2 ppm/° C.) of the IC dies than the thermal expansion coefficient (e.g., about 40 ppm/° C. to about 80 ppm/° C.) of the molding compound layer. In some embodiments, the thermal expansion coefficient of the material can be between about 5 ppm/° C. to about 10 ppm/° C. In some embodiments, the material can include copper, aluminum, nickel, invar, or other suitable materials with thermal expansion coefficients between the thermal expansion coefficients of the molding compound layer and the IC dies. In some embodiments, the frame structure can be attached to the top surface of the bottom hybrid bonding structure with epoxy, die attach films, or other suitable adhesive materials.

The placement of the frame structure in the molding compound layer replaces a volume of the high thermal expansion coefficient material of the molding compound layer with the lower thermal expansion coefficient material of the frame structure. As a result, the overall thermal expansion coefficient of materials surrounding the IC dies can be reduced, and consequently, the thermal expansion induced peeling stress at the hybrid bonding interfaces can be prevented or reduced. In addition, with the use of the frame structure, warpage of the IC dies caused by the greater thermal expansion of the molding compound layer during high temperature processing can be prevented or reduced. Preventing or reducing the warpage of the IC dies can improve the bonding between the IC dies and underlying interposer dies and/or others substrates of the IC die package, thus improving the bonding reliability of the IC die package.

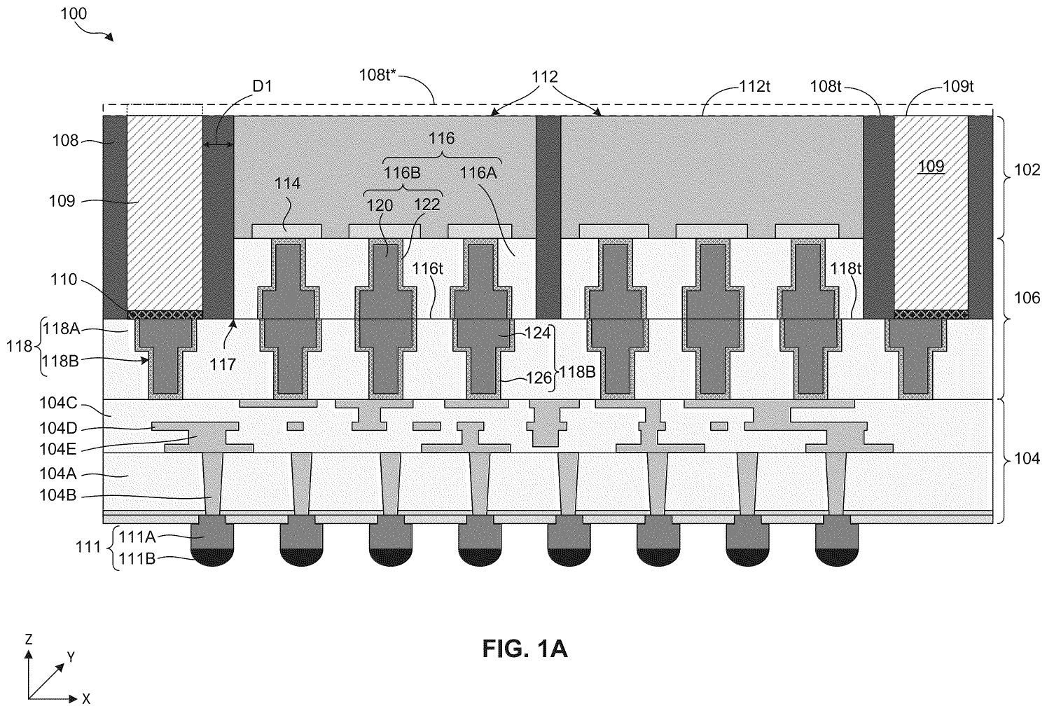

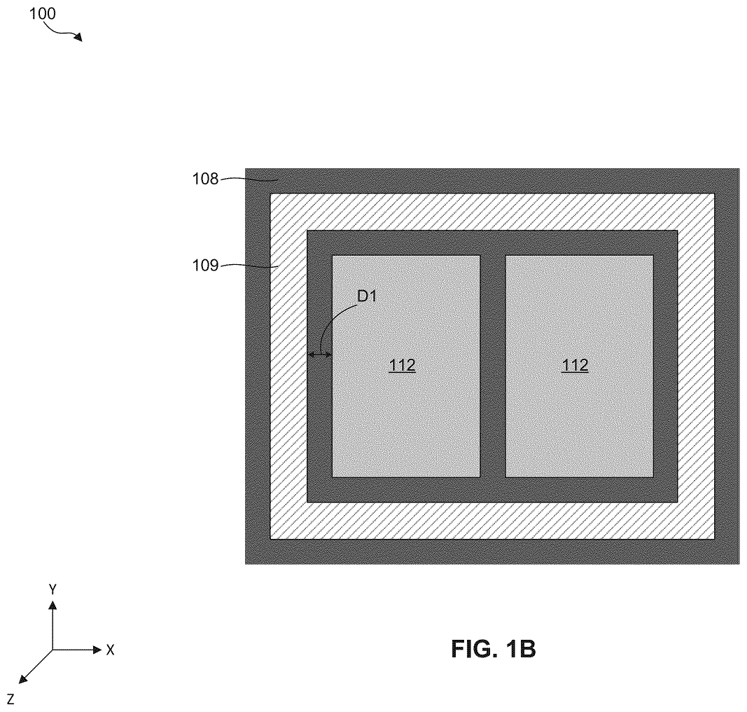

FIG. 1A illustrates a cross-sectional view of an IC die package 100 (also referred to as an “IC chip package 100”), according to some embodiments. FIG. 1B illustrates a top-down view of IC die package 100, according to some embodiments. The discussion of elements in FIGS. 1A and 1B with the same annotations applies to each other, unless mentioned otherwise.

In some embodiments, IC die package 100 can include (i) a die layer 102, (ii) a routing layer 104, (iii) a bonding layer 106, (iv) a molding compound layer 108 (also referred to as “encapsulation layer 108”), (v) a frame structure 109, (vi) an adhesive layer 110, and (vii) conductive bonding structures 111.

Referring to FIGS. 1A and 1B, in some embodiments, die layer 102 can include one or more IC dies 112 (also referred to as “top dies 112”), each of which can include a high-performance IC die, such as an SoC die, a micro control unit (MCU) die, a microprocessor unit (MPU) die, an accelerated processing unit (APU) die, a central processing unit (CPU) die, a graphics processing unit (GPU) die, and a combination thereof. Though two IC dies 112 are shown in die layer 102, any number of IC dies 112 can be included in die layer 102. IC dies 112 can similar to or different from each other. In some embodiments, adjacent IC dies 112 can be separated from each other by a lateral distance of about 50 μm to about 70 μm. In some embodiments, IC die 112 can include interconnect structures 114, which can electrically connect devices (not shown) in IC die 112 to underlying routing layer 104 through bonding layer 106. In some embodiments, IC dies 112 can be electrically connected to each other through bonding layer 106 and routing layer 104. In some embodiments, die layer 102 can be electrically connected to overlying die layers or other elements (not shown) of IC die package 100 through a redistribution layer (not shown) or a bonding layer similar to bonding layer 106.

Referring to FIG. 1A, in some embodiments, routing layer 104 can include an interposer die having (i) a semiconductor substrate 104A, (ii) conductive through-vias 104B disposed in semiconductor substrate 104A, (iii) a dielectric layer 104C disposed on semiconductor substrate 104A, (iv) metal lines 104D disposed in dielectric layer 104C, and (v) metal vias 104E disposed in dielectric layer 104C. In some embodiments, semiconductor substrate 104A can include a silicon substrate. In some embodiments, conductive through-vias 104B can include a metal (such as copper and aluminum), a metal alloy (such as copper alloy and aluminum alloy), or a combination thereof. In some embodiments, dielectric layer 104C can include a stack of dielectric layers. In some embodiments, routing layer 104 can be electrically bonded to an underlying package substrate, other substrates, or other dies (not shown) through conductive bonding structures 111. In some embodiments, each of conductive bonding structures 111 can include copper (Cu) bumps 111A and solder bumps 111B. The package substrate can be disposed on and electrically connected to a circuit board (not shown) and can electrically connect IC die package 100 to external devices through the circuit board.

In some embodiments, bonding layer 106 can include one or more first hybrid bonding structures 116 (also referred to as “top hybrid bonding structures 116”) and a second hybrid bonding structure 118 (also referred to as a “bottom hybrid bonding structure 118”). A bottom surface of each first hybrid bonding structure 116 can be disposed on and electrically connected to interconnect structures 114 of a corresponding IC die 112. A top surface (also referred to as a “bonding surface”) of each first hybrid bonding structure 116 can be disposed on and bonded to a top surface of second hybrid bonding structure 118 through hybrid bonds, as described in detail below. The interfaces between first and second hybrid bonding structures 116 and 118 can be referred to as “hybrid bonding interfaces 117.” The bonding reliability between first and second hybrid bonding structures 116 and 118 can be improved by reducing the risk of delamination between first and second hybrid bonding structures 116 and 118 at hybrid bonding interface 117 with the use of frame structure 109, as discussed in detail below.

In some embodiments, each first hybrid bonding structure 116 can include a first dielectric layer 116A and one or more first conductive structures 116B disposed in first dielectric layer 116A. Though three first conductive structures 116B are shown in each first hybrid bonding structure 116, any number of first conductive structures 116B can be included in first hybrid bonding structure 116. In some embodiments, first dielectric layers 116A can include silicon oxide (SiO₂), silicon nitride (SiN), silicon carbide (SiC), silicon oxynitride (SiON), silicon carbon nitride (SiCN), or any other suitable dielectric material. In some embodiments, each first conductive structure 116B can include a first conductive plug 120 and a first liner 122 surrounding first conductive plug 120. In some embodiments, first conductive structures 116B can be liner-free (not shown). Top surfaces of first conductive plugs 120 and first liners 122 can be substantially coplanar with top surface 116t of first dielectric layer 116A. In some embodiments, first conductive plugs 120 can include a conductive material, such as copper (Cu), cobalt (Co), aluminum (Al), any other suitable conductive material, and a combination thereof. In some embodiments, first liners 122 can include a conductive material the same as or different from the material of first conductive plugs 120. In some embodiments, first liners 122 can include titanium (Ti), Cu, or other suitable conductive material.

In some embodiments, second hybrid bonding structure 118 can include a second dielectric layer 118A and one or more second conductive structures 118B disposed in second dielectric layer 118A. Though eight second conductive structures 118B are shown in second hybrid bonding structure 118, any number of second conductive structures 118B can be included in second hybrid bonding structure 118. In some embodiments, second dielectric layer 118A can include a dielectric material the same as or different from first dielectric layer 116A. In some embodiments, each of second conductive structures 118B can include a second conductive plug 124 and a second liner 126 surrounding second conductive plug 124. In some embodiments, second conductive structures 118B can be liner-free (not shown). Top surfaces of second conductive plugs 124 and second liners 126 can be substantially coplanar with top surface 118t of second dielectric layer 118A. In some embodiments, second conductive plugs 124 and second liners 126 can include a conductive material the same as or different from first conductive plugs 120 and first liners 122, respectively.

First and second dielectric layers 116A and 118A can be bonded to each other through dielectric-to-dielectric fusion bonds, and first and second conductive structures 116B and 118B can be bonded to each other through metal-to-metal bonds. The dielectric-to-dielectric fusion bonds and metal-to-metal bonds can be at hybrid bonding interface 117. In some embodiments, the number of second conductive structures 118B can be equal to the total number of first conductive structures 116B. Each second conductive structure 118B can be bonded to a corresponding one of first conductive structures 116B.

Referring to FIGS. 1A and 1B, in some embodiments, molding compound layer 108 can surround each IC die 112 and each first hybrid bonding structure 116 and can be disposed on second hybrid bonding structure 118. Molding compound layer 108 can be disposed between adjacent IC dies and between adjacent first hybrid bonding structures 116. In some embodiments, molding compound layer 108 can be disposed directly on sidewalls of IC dies 112, directly on first dielectric layers 116A of first hybrid bonding structures 116, and directly on top surface 118t of second dielectric layer 118A of second hybrid bonding structure 118. In some embodiments, the interfaces between molding compound layer 108 and top surface 118t of second dielectric layer 118A can be substantially coplanar with hybrid bonding interface 117. In some embodiments, molding compound layer 108 can include a molding compound, an epoxy, a resin, or any other suitable encapsulation material.

Frame structure 109 can be configured to prevent or reduce the thermal expansion induced peeling stress at hybrid bonding interface 117. In addition, frame structure 109 can be configured to prevent or reduce the warping of IC dies 112 caused by the thermal expansion of molding compound layer 108 during high temperature processing. Preventing or reducing the thermal expansion induced peeling stress at hybrid bonding interface 117 and the warpage of IC dies 112 can improve the bonding reliability of IC die package 100. In some embodiments, frame structure 109 can be positioned in molding compound layer 108 and on top surface 118t of second hybrid bonding structure 118. In addition, frame structure 109 can surround IC dies 112 and first hybrid bonding structures 116. That is, IC dies 112 and first hybrid bonding structures 116 can be in a region enclosed by frame structure 109. In some embodiments, frame structure 109 can be attached on top surface 118t of second hybrid bonding structure 118 with adhesive layer 110 having an epoxy layer, a die attach film (DAF), or other suitable adhesive materials.

In some embodiments, frame structure 109 can include a material with a thermal expansion coefficient lower than the thermal expansion coefficient of molding compound layer 108. In some embodiments, the thermal expansion coefficient of the material can be between the thermal expansion coefficients of molding compound layer 108 and IC dies 112. In some embodiments, the thermal expansion coefficient of the material can be closer to the thermal expansion coefficient (e.g., about 2 ppm/° C.) of IC dies 112 than the thermal expansion coefficient (e.g., about 40 ppm/° C. to about 80 ppm/° C.) of molding compound layer 108. In some embodiments, the thermal expansion coefficient of the material can be between about 5 ppm/° C. and about 10 ppm/° C. In some embodiments, frame structure 109 can be placed at a lateral distance D1 of about 50 μm to about 60 μm away from the outermost IC dies 112. Within these ranges of thermal expansion coefficient of the material and distance D1, frame structure 109 can prevent or reduce the thermal expansion induced peeling stress at hybrid bonding interface 117 and/or prevent or reduce thermal expansion induced warping of IC dies 112. In some embodiments, the material of frame structure 109 can include copper, aluminum, nickel, invar, or other suitable materials with thermal expansion coefficients between the thermal expansion coefficients of molding compound layer 108 and IC dies 112.

In some embodiments, top surface 109t of frame structure 109 can be substantially coplanar with top surface 108t of molding compound layer 108 and top surface 112t of IC dies 112. In some embodiments, frame structure 109 can be embedded in molding compound layer 108 and top surface 109t of frame structure 109 can be below top surface 108t of molding compound layer 108 and top surface 112t of IC dies 112. In some embodiments, molding compound layer 108 can extend above IC dies 112 and frame structure 109 as shown with dashed line in FIG. 1A and top surface 108t* of the extended molding compound layer 108 can be above top surface 109t of frame structure 109 and top surface 112t of IC dies 112. In some embodiments, frame structure 109 can extend up to top surface 108t* of the extended molding compound layer 108 and can be above top surface 112t of IC dies 112. In some embodiments, frame structure 109 can be attached to second dielectric layer 118A and second conductive structures 118B through adhesive layers 110. In some embodiments, frame structure 109 can be attached to second dielectric layer 118A through adhesive layers 110 when second conductive structures 118B are absent under frame structure 109.

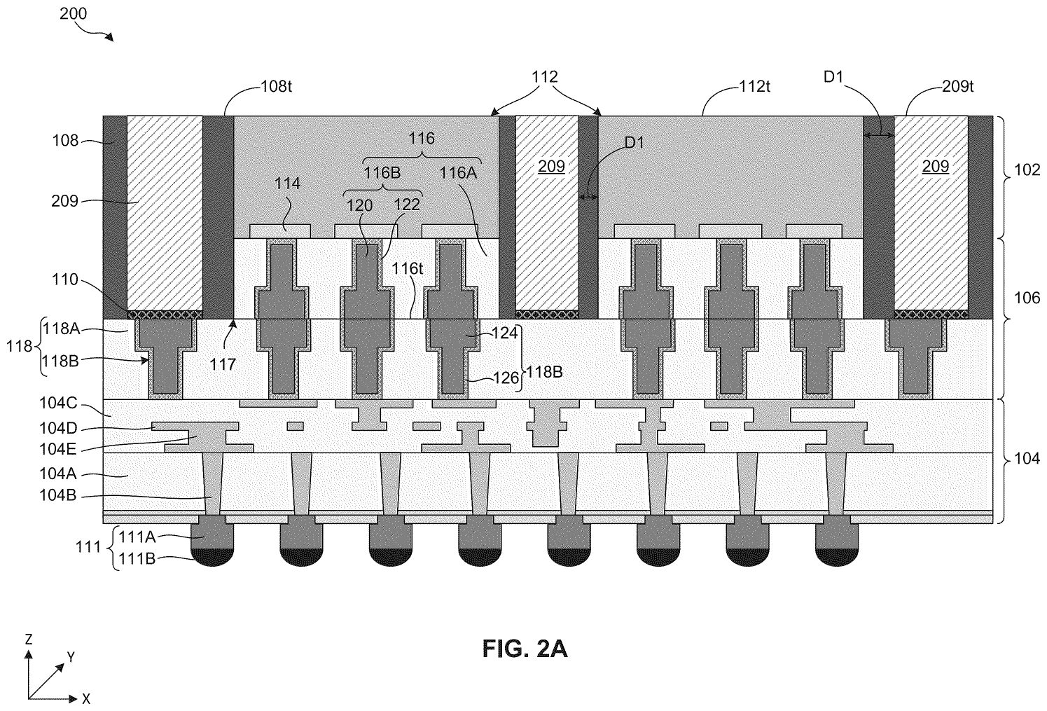

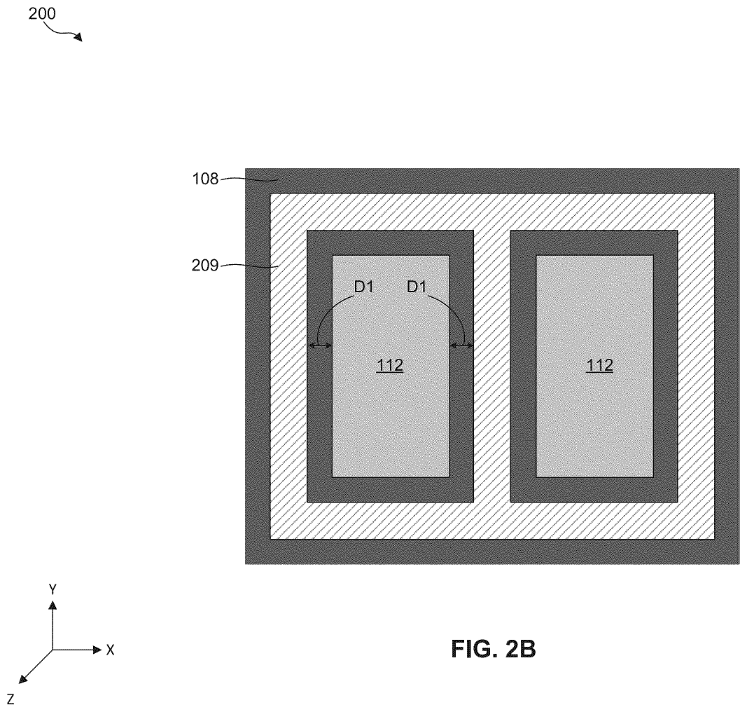

FIG. 2A illustrates a cross-sectional view of an IC die package 200, according to some embodiments. FIG. 2B illustrates a top-down view of IC die package 200, according to some embodiments. The discussion of IC die package 100 applies to IC die package 200, unless mentioned otherwise. The discussion of elements in FIGS. 1A, 1B, 2A, and 2B with the same annotations applies to each other, unless mentioned otherwise. In some embodiments, IC die package 200 can include a frame structure 209. The discussion of frame structure 109 applies to frame structure 209, unless mentioned otherwise. Frame structure 209 can be in molding compound layer 108 and on top surface 118t of second hybrid bonding structure 118. In addition, frame structure 209 can surround each IC die 112 and each first hybrid bonding structure 116. Thus, each IC die 112 can be separated from adjacent IC dies 112 by a portion of molding compound layer 108 and frame structure 209.

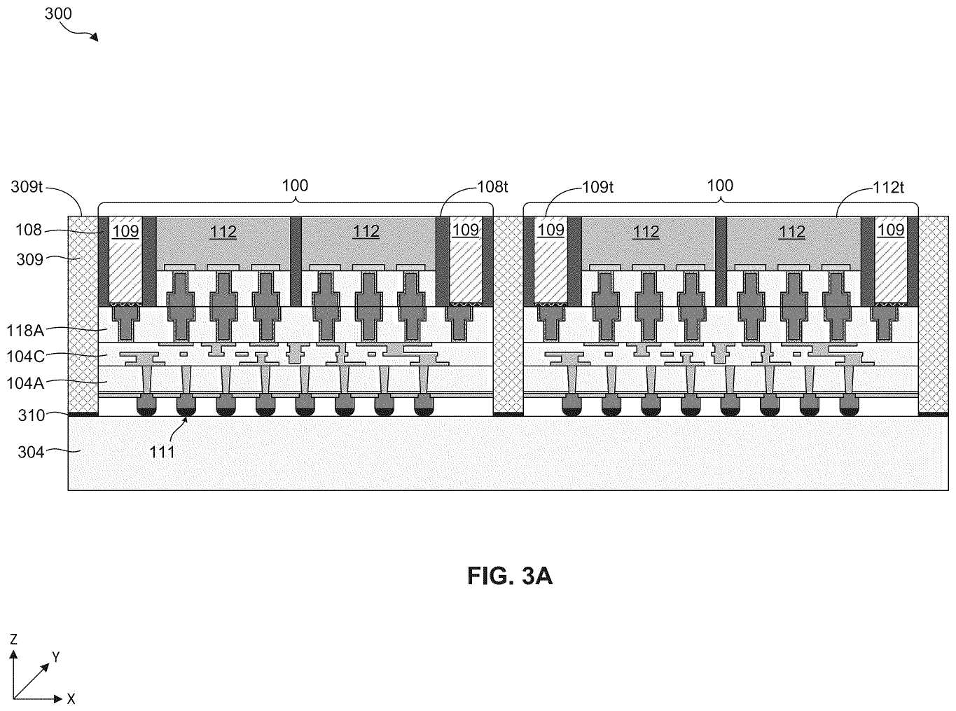

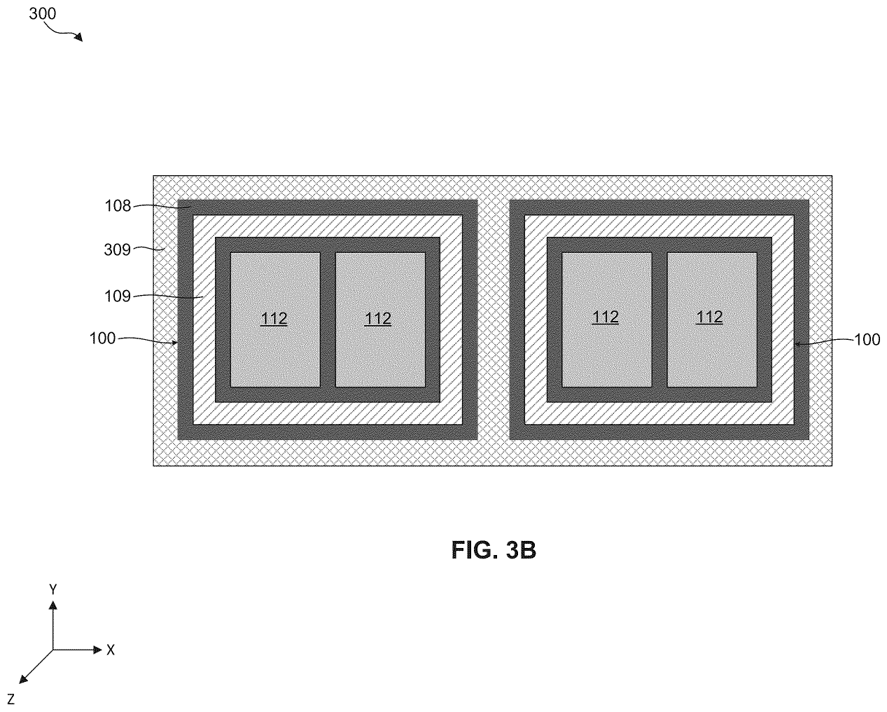

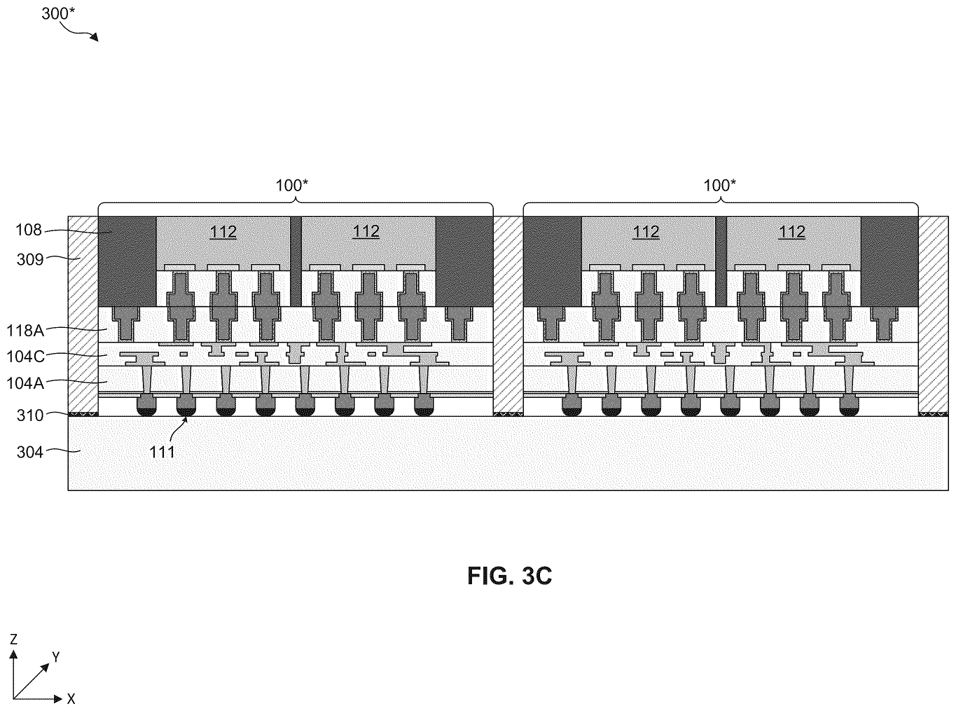

FIG. 3A illustrates a cross-sectional view of an IC die package 300, according to some embodiments. FIG. 3B illustrates a top-down view of IC die package 300, according to some embodiments. The discussion of IC die package 100 applies to IC die package 300, unless mentioned otherwise. The discussion of elements in FIGS. 1A, 1B, 3A, and 3B with the same annotations applies to each other, unless mentioned otherwise. In some embodiments, IC die package 300 can include a substrate 304 (e.g., package substrate 304 or a wafer 304) and IC die packages 100 on substrate 304. In some embodiments, IC die packages 100 may not have conductive bonding structures 111 and semiconductor substrates 104A of IC die packages 100 can be directly on substrate 304.

IC die package 300 can further include a frame structure 309 on substrate 304 and surrounding each IC die package 100. Frame structure 309 can be attached to substrate 304 with an adhesive layer 310 having an epoxy layer, a DAF, or other suitable adhesive materials. The discussion of frame structure 109 applies to frame structure 309, unless mentioned otherwise. Sidewalls of frame structure 309 can be in contact with sidewalls of (i) molding compound layers 108, (ii) second dielectric layer 118A, (iii) dielectric layer 104C, and (iv) semiconductor substrate 104A. In some embodiments, top surface 309t of frame structure 309 can be substantially coplanar with top surfaces 108t of molding compound layers 108, top surfaces 109t of frame structures 109, and top surfaces 112t of IC dies 112.

FIG. 3C illustrates a cross-sectional view of an IC die package 300*, according to some embodiments. The discussion of IC die package 300 applies to IC die package 300*, unless mentioned otherwise. The discussion of elements in FIGS. 1A, 1B, 3A, 3B, and 3C with the same annotations applies to each other, unless mentioned otherwise. IC die package 300* can include IC die packages 100* on substrate 304. The discussion of IC die package 100 applies to IC die package 100*, unless mentioned otherwise. Unlike IC die package 100, IC die packages 100* may not include frame structures 109 in molding compound layers 108. Frame structure 309 can limit the thermal expansion of molding compound layers 108 and prevent or reduce the thermal expansion induced peeling stress at hybrid bonding interface 117 and/or the warping of IC dies 112.

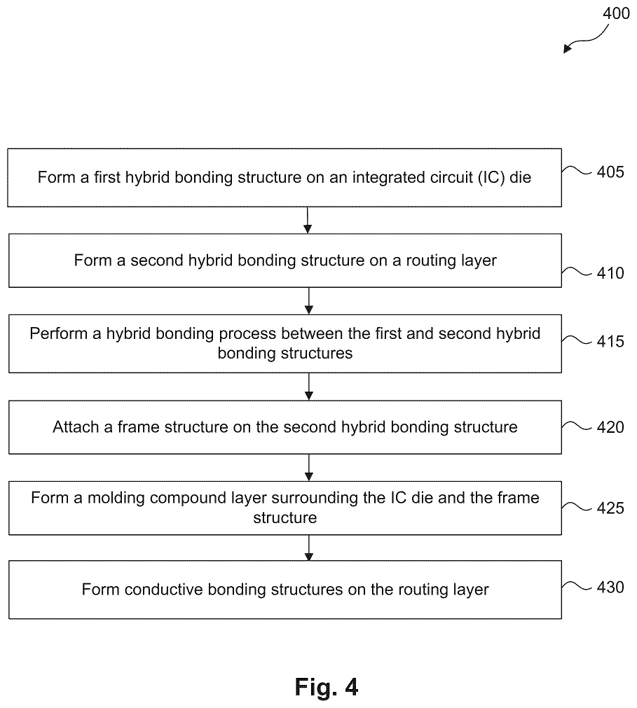

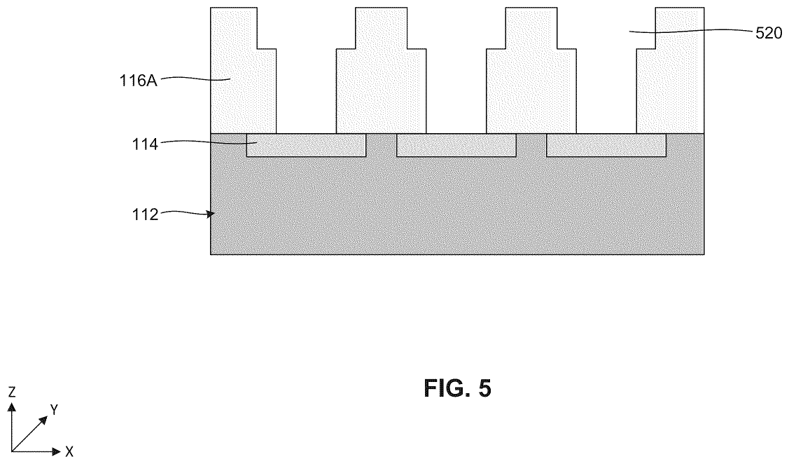

FIG. 4 is a flow diagram of an example method 400 for fabricating IC die package 100 shown in FIG. 1A, according to some embodiments. For illustrative purposes, the operations illustrated in FIG. 4 will be described with reference to the example fabrication process for fabricating IC die package 100 as illustrated in FIGS. 5-18. FIGS. 5-18 are cross-sectional views of IC die package 100 at various stages of fabrication, according to some embodiments. Operations can be performed in a different order or not performed depending on specific applications. It should be noted that method 400 may not produce a complete IC die package 100. Accordingly, it is understood that additional processes can be provided before, during, and after method 400, and that some other processes may only be briefly described herein. The discussion of elements in FIGS. 1A, 1B, and 5-18 with the same annotations applies to each other, unless mentioned otherwise.

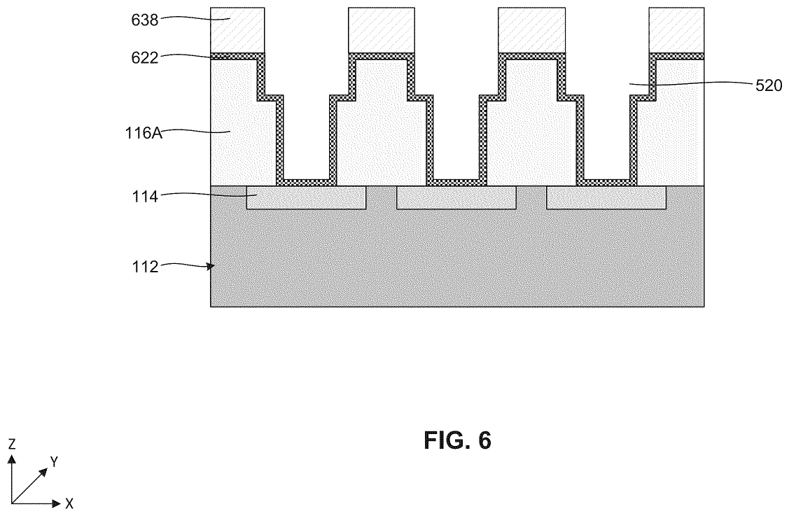

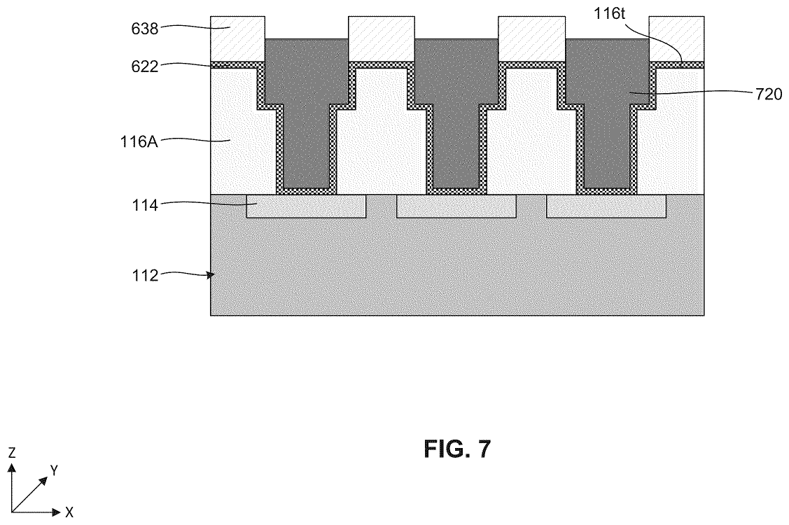

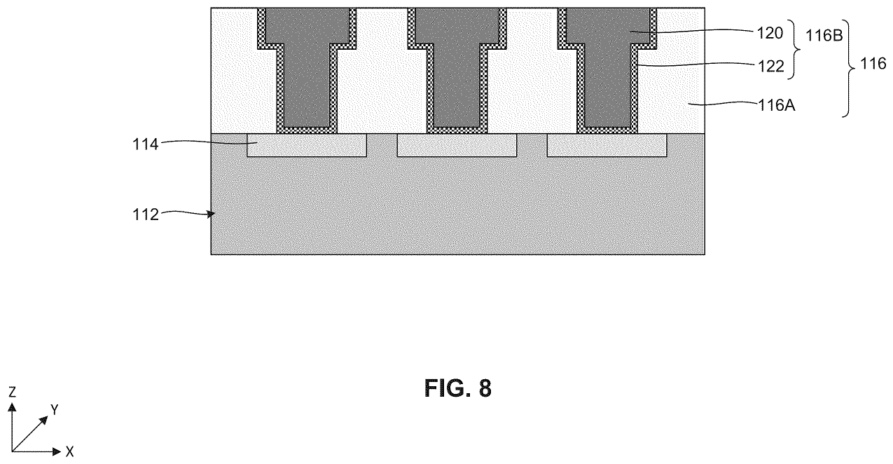

Referring to FIG. 4, in operation 405, a first hybrid bonding structure is formed on an IC die. For example, as described with reference to FIGS. 5-8, first hybrid bonding structure 116 is formed on IC die 112. In some embodiments, the formation of first hybrid bonding structure 116 can include sequential operations of (i) depositing first dielectric layer 116A on IC die 112, as shown in FIG. 5, (ii) etching first dielectric layer 116A to form openings 520 on interconnect structures 114, as shown in FIG. 5, (iii) depositing a conductive layer 622 having the material of first liner 122 on top surfaces 116t of first dielectric layer 116A and along sidewalls of openings 520, as shown in FIG. 6, (iv) forming a patterned photoresist layer 638 on conductive layer 622, as shown in FIG. 6, (v) depositing, using an electroplating process or other suitable conductive material deposition process, a conductive layer 720 having the material of first conductive plug 120 to fill openings 520 and extend a distance over top surfaces 116t of first dielectric layer 116A, as shown in FIG. 7, (vi) removing patterned photoresist layer 638, as shown in FIG. 8, and (vii) performing a chemical mechanical polishing (CMP) process to coplanarize top surfaces of first conductive plugs 120 and first liners 122 with top surfaces 116t of first dielectric layer 116A, as shown in FIG. 8. In some embodiments, operation (iii) can be omitted to form first hybrid bonding structure 116 without first liner 122.

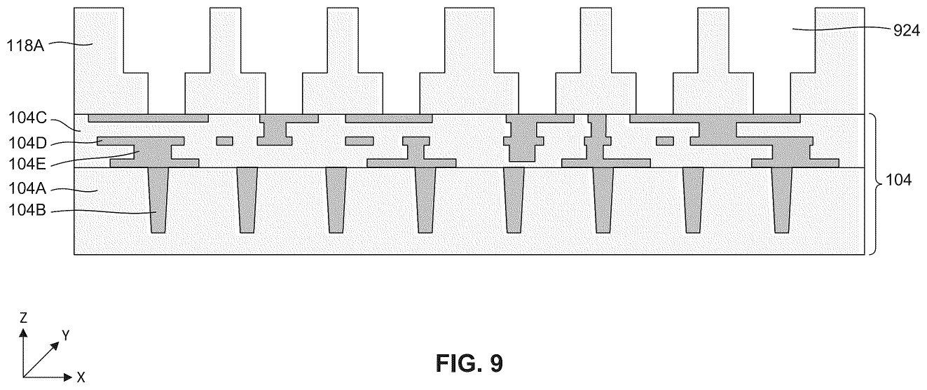

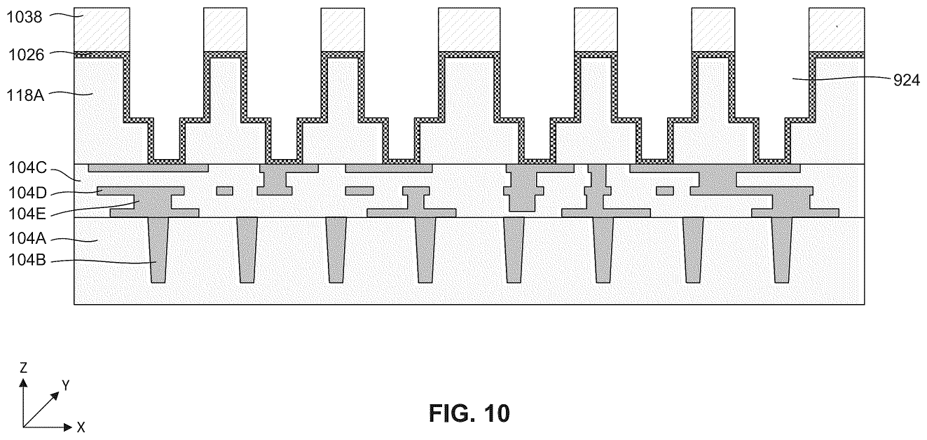

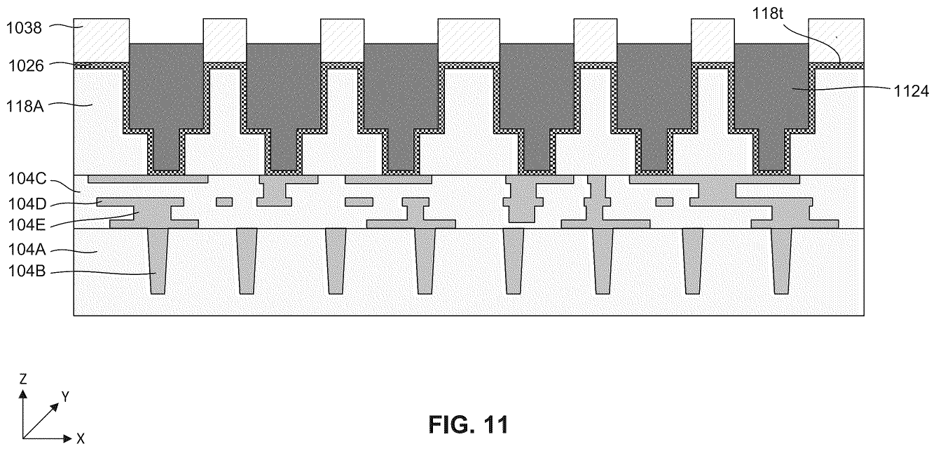

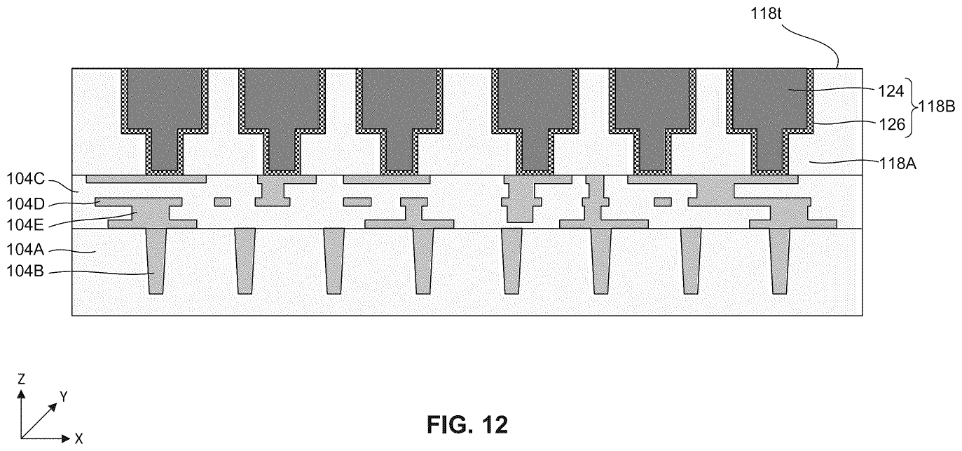

Referring to FIG. 4, in operation 410, a second hybrid bonding structure is formed on a routing layer. For example, as described with reference to FIGS. 9-12, second hybrid bonding structure 118 is formed on routing layer 104. In some embodiments, the formation of second hybrid bonding structure 118 can include sequential operations of (i) depositing second dielectric layer 118A on routing layer 104, as shown in FIG. 9, (ii) etching second dielectric layer 124 to form openings 924 on metal lines 104D, as shown in FIG. 9, (iii) depositing a conductive layer 1026 having the material of second liner 126 on top surfaces 118t of second dielectric layer 124 and along sidewalls of openings 1026, as shown in FIG. 10, (iv) forming a patterned photoresist layer 1038 on conductive layer 1026, as shown in FIG. 10, (v) depositing, using an electroplating process or other suitable conductive material deposition process, a conductive layer 1124 having the material of second conductive plug 124 to fill openings 924 and extend a distance over top surfaces 118t of second dielectric layer 118A, as shown in FIG. 11, (vi) removing patterned photoresist layer 1038, as shown in FIG. 12, and (vii) performing a CMP process to coplanarize top surfaces of second conductive plugs 124 and second liners 126 with top surfaces 118t of second dielectric layer 118A, as shown in FIG. 12. In some embodiments, operation (iii) can be omitted to form second hybrid bonding structure 118 without second liners 126. In some embodiments, operation 410 can be formed prior to operation 405 and operation 415 can follow operation 405.

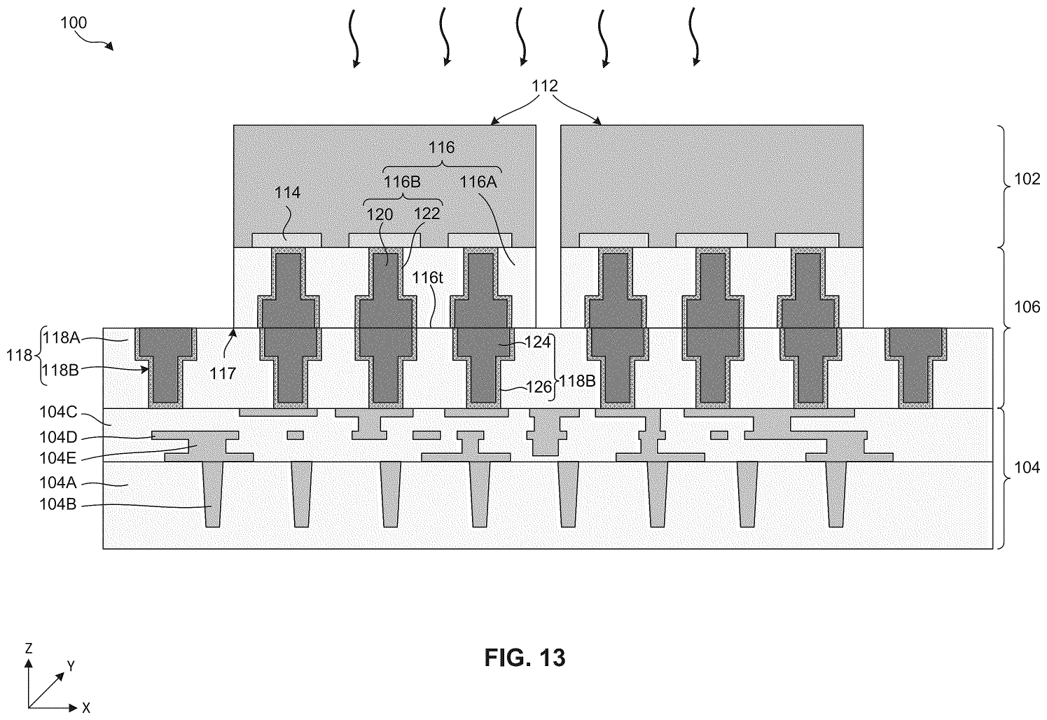

Referring to FIG. 4, in operation 415, a hybrid bonding process is performed between the first and second hybrid bonding structures. For example, as described with reference to FIG. 13, a hybrid bonding process is performed between first and second hybrid bonding structures 116 and 118. In some embodiments, performing the hybrid bonding process can include sequential operations of (i) performing an activation process with a plasma (e.g., hydrogen plasma) on top surfaces of first dielectric layer 116A, first conductive structures 116B, second dielectric layer 118A, and second conductive structures 118B, (ii) aligning first conductive structures with corresponding second conductive structures 118B and bringing top surfaces 116t of first dielectric layer 116A in contact with top surfaces 118t of second dielectric layer 118A, as shown in FIG. 13, and (iii) performing an anneal process on the structure of FIG. 13 at a temperature lower than the melting temperature of the material of first and second conductive plugs 120 and 124 to form the structure of FIG. 13. In some embodiments, first and second conductive structures 116B and 118B may be not be in contact with each other after the aligning in operation (ii) and there may be air gaps present between first and second conductive structures 116B and 118B. First and second conductive structures 116B and 118B can expand and make contact with each other during the anneal process to form the metal-to-metal fusion bonds.

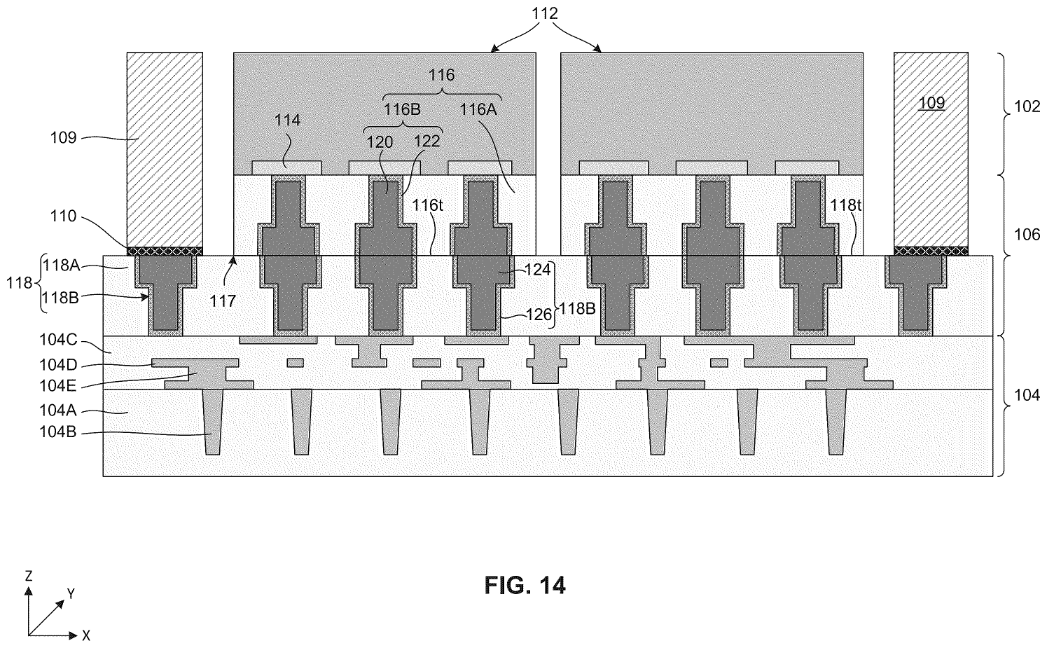

Referring to FIG. 4, in operation 420, a frame structure is attached on the second hybrid bonding structure. For example, as shown in FIG. 14, frame structure 109 is attached on top surface 118t of second hybrid bonding structure 118 with adhesive layer 110. In some embodiments, frame structure 109 can be a pre-formed metal structure and can placed on top surface 118t of second hybrid bonding structure 118.

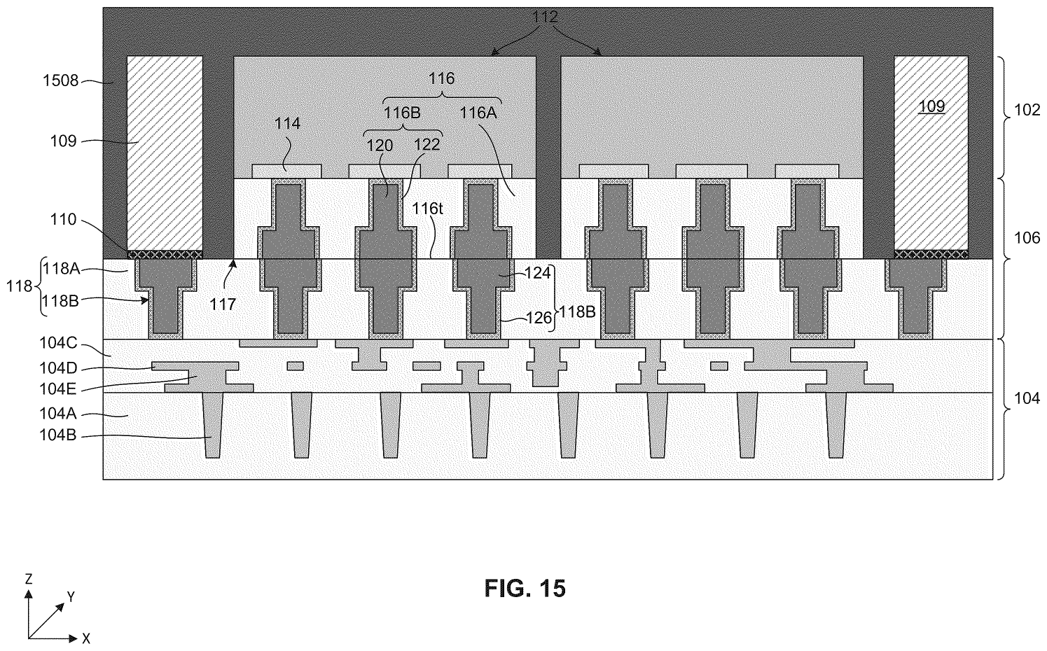

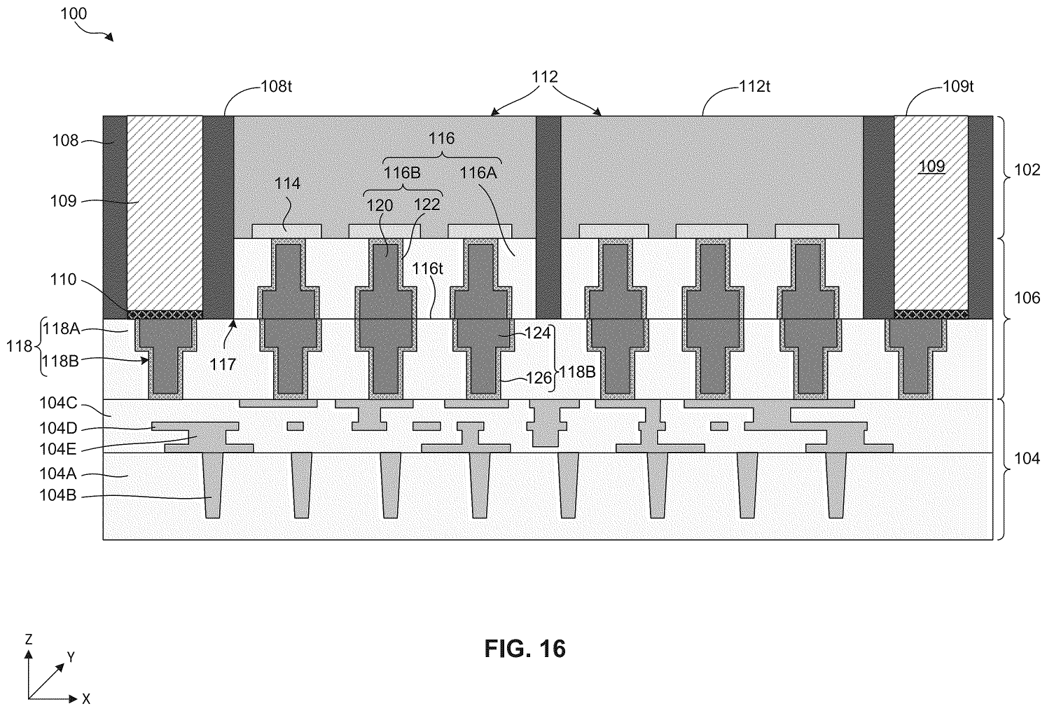

Referring to FIG. 4, in operation 425, a molding compound layer is formed surrounding the IC die and the frame structure. For example, as described with reference to FIGS. 15 and 16, molding compound layer 108 is formed surrounding IC dies 112 and frame structure 109. The formation of molding compound layer 108 can include forming a molding compound layer 1508 on the structure of FIG. 14 using a compression molding or a transfer molding process to form the structure of FIG. 15, and performing a CMP process on molding compound layer 1508 to form molding compound layer 108, as shown in FIG. 16.

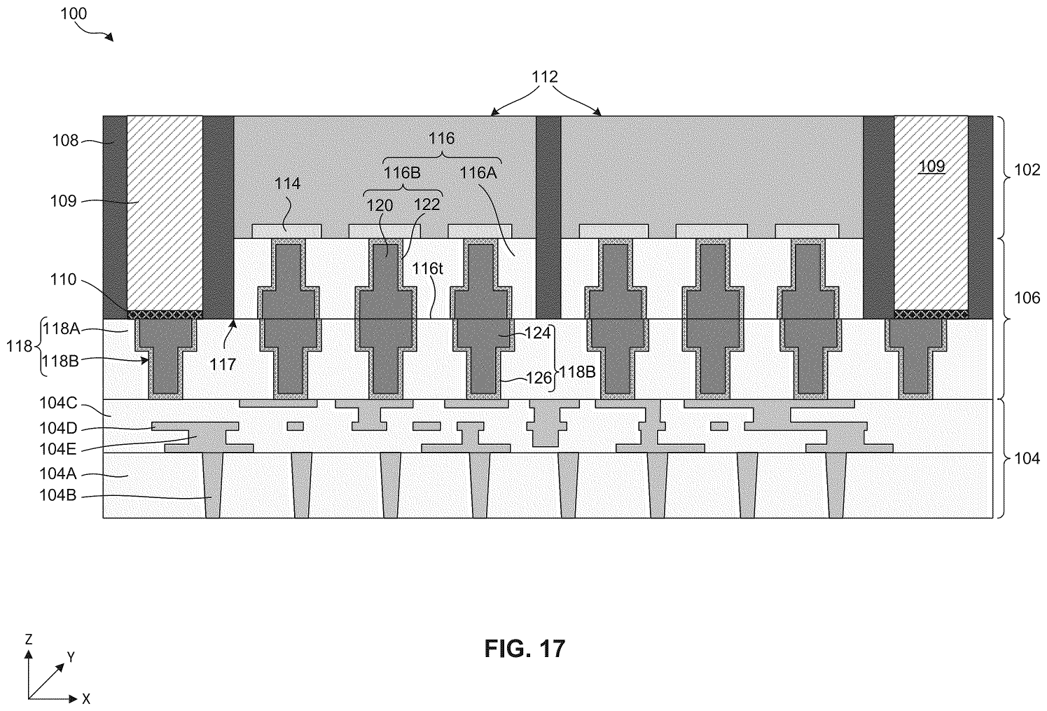

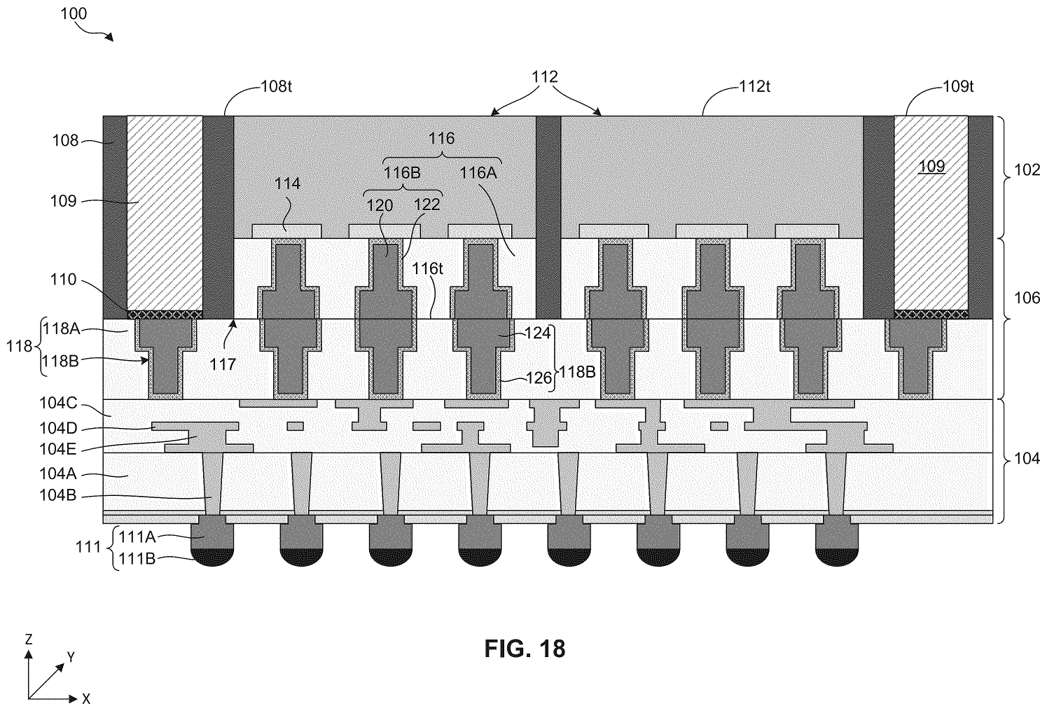

Referring to FIG. 4, in operation 430, conductive bonding structures are formed on the routing layer. For example, as described with reference to FIGS. 17 and 18, conductive bonding structures 111 are formed on routing layer 104. In some embodiments, the formation of conductive structures can include sequential operations of (i) performing a CMP process or an etching process on semiconductor substrate 104A to expose bottom surfaces 104Bs of conductive through-vias 104B, as shown in FIG. 17, and (ii) forming conductive bonding structures 111 on bottom surfaces 104Bs, as shown in FIG. 18.

In some embodiments, IC die package 200 can be fabricated with operations similar to operations 405-430 of method 400, except in operation 420, frame structure 209 is attached on top surface 118t of second hybrid bonding structure 118 with adhesive layer 110 instead of frame structure 109.

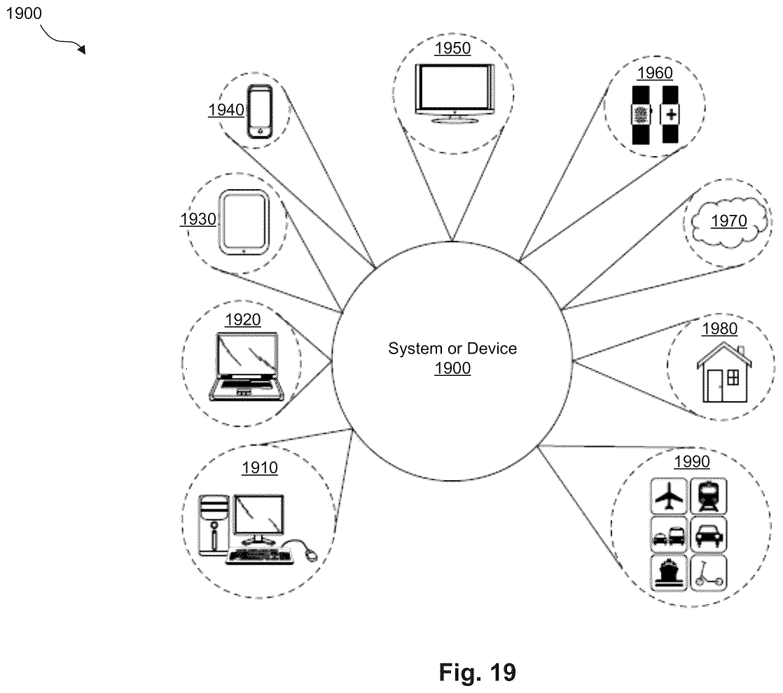

FIG. 19 is an illustration of exemplary systems or devices that can include the disclosed embodiments. System or device 1900 can incorporate one or more of the disclosed embodiments in a wide range of areas. For example, system or device 1900 can be implemented in one or more of a desktop computer 1910, a laptop computer 1920, a tablet computer 1930, a cellular or mobile phone 1940, and a television 1950 (or a set-top box in communication with a television).

Also, system or device 1900 can be implemented in a wearable device 1960, such as a smartwatch or a health-monitoring device. In some embodiments, the smartwatch can have different functions, such as access to email, cellular service, and calendar functions. Wearable device 1960 can also perform health-monitoring functions, such as monitoring a user's vital signs and performing epidemiological functions (e.g., contact tracing and providing communication to an emergency medical service). Wearable device 1960 can be worn on a user's neck, implantable in user's body, glasses or a helmet designed to provide computer-generated reality experiences (e.g., augmented and/or virtual reality), any other suitable wearable device, and combinations thereof.

Further, system or device 1900 can be implemented in a server computer system, such as a dedicated server or on shared hardware that implements a cloud-based service 1970. System or device 1900 can be implemented in other electronic devices, such as a home electronic device 1980 that includes a refrigerator, a thermostat, a security camera, and other suitable home electronic devices. The interconnection of such devices can be referred to as the “Internet of Things” (IoT). System or device 1900 can also be implemented in various modes of transportation 1990, such as part of a vehicle's control system, guidance system, and/or entertainment system. The systems and devices illustrated in FIG. 19 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
an integrated circuit (IC) die;
an interposer die electrically connected to the IC die;
a first bonding structure disposed on the IC die;
a second bonding structure bonded to the first bonding structure;
a molding compound layer disposed on the second bonding structure; and
a frame structure disposed on the second bonding structure and surrounding the IC die.

2. The structure of claim 1, wherein the frame structure surrounds the first bonding structure.

3. The structure of claim 1, wherein the frame structure is disposed in the molding compound layer.

4. The structure of claim 1, wherein the frame structure comprises a thermal expansion coefficient lower than a thermal expansion coefficient of the molding compound layer.

5. The structure of claim 1, wherein the frame structure comprises a thermal expansion coefficient higher than a thermal expansion coefficient of the IC die and lower than a thermal expansion coefficient of the molding compound layer.

6. The structure of claim 1, wherein the frame structure comprises a thermal expansion coefficient of about 5 ppm/° C. to about 10 ppm/° C.

7. The structure of claim 1, wherein the frame structure comprises a metal frame structure.

8. The structure of claim 1, wherein the frame structure comprises copper, aluminum, nickel, or invar.

9. The structure of claim 1, wherein a top surface of the frame structure is substantially coplanar with a top surface of the molding compound layer.

10. The structure of claim 1, further comprising an adhesive layer disposed between the frame structure and the second bonding structure.

11. An integrated circuit (IC) die package, comprising:
first and second IC dies;
first and second bonding structures disposed on the first and second IC dies, respectively;
a third bonding structure bonded to the first and second bonding structures and disposed on a substrate;
a molding compound layer surrounding each of the first and second IC dies; and
a frame structure surrounding each of the first and second IC dies and disposed in the molding compound layer.

12. The IC die package of claim 11, wherein the frame structure comprises a thermal expansion coefficient higher than thermal expansion coefficients of the first and second IC dies and lower than a thermal expansion coefficient of the molding compound layer.

13. The IC die package of claim 11, wherein the frame structure comprises a metal frame structure.

14. The IC die package of claim 11, wherein the frame structure surrounds each of the first and second bonding structures.

15. The IC die package of claim 11, wherein the frame structure is attached to a top surface of the third bonding structure.

16. The IC die package of claim 11, wherein the frame structure comprises a thermal expansion coefficient of about 5 ppm/° C. to about 10 ppm/° C.

17. A method, comprising:
forming a first bonding structure on an integrated circuit (IC) die;
forming a second bonding structure on an interposer die;
performing a bonding process between the first and second bonding structures;
attaching a frame structure on a top surface of the second bonding structure; and
performing a molding process to form a molding compound layer surrounding the IC die and the frame structure.

18. The method of claim 17, wherein attaching the frame structure comprises attaching the frame structure to the top surface with an epoxy layer or a die attach film.

19. The method of claim 17, wherein attaching the frame structure comprises placing a metal frame structure on the top surface of the second bonding structure.

20. The method of claim 17, wherein performing the bonding process comprises performing a hybrid bonding process.
